(19) United States
(12) Patent Application Publication
(10) Pub. No.: US 2013/0092237 A1
(43) Pub. Date: Apr. 18, 2013

(54) ELECTROCHEMICAL PHOTOVOLTAIC CELLS

(71) Applicants: Arash Takshi, Tampa, FL (US); John D.W. Madden, Vancouver (CA); John T. Beatty, Vancouver (CA)

(72) Inventors: Arash Takshi, Tampa, FL (US); John D.W. Madden, Vancouver (CA); John T. Beatty, Vancouver (CA)

(73) Assignee: THE UNIVERSITY OF BRITISH COLUMBIA, Vancouver, BC (CA)

(21) Appl. No.: 13/635,895

(22) PCT Filed: Mar. 18, 2011
(86) PCT No.: PCT/CA2011/000296

§ 371 Date: Dec. 27, 2012

Related U.S. Application Data
(60) Provisional application No. 61/315,622, filed on Mar. 19, 2010.

(51) Int. Cl. H01L 51/42

(52) U.S. Cl. CPC H01L 51/424
USPC 136/263; 136/252

(57) ABSTRACT

The invention provides a bio-photovoltaic device, in which a photoelectric center, exemplified by a biological photosynthetic reaction center (RC), is dispersed and mobile in a medium, such as an aqueous solution. The charges generated by the illuminated RC are transferred to electrodes via one or more mediators. In selected embodiments, the difference between the reaction rates of two types of mediator at the electrode surfaces, in conjunction with other charge transfer reaction equilibria, determines the direction of the photocurrent in the device. In an exemplified embodiment, the magnitude of the photocurrent is proportional to the incident light intensity, and the current increases nonlinearly with an increase in the RC concentration in the medium.

### FIELD OF THE INVENTION

The invention is in the field of electrochemistry, providing photovoltaic devices that incorporate a fluid medium containing a photoelectric center, such as a biological photosynthetic reaction center in an aqueous medium, and charge transfer mediators, such as small molecule redox species, together with selected electrodes, arranged in a cell adapted to generate a photocurrent in response to light.

### BACKGROUND OF THE INVENTION

The conversion of sunlight directly into electricity typically involves the use of solid state solar cells in photovoltaic arrays. To store the electrical energy, an electrochemical device such as a battery is typically used.

The use of biological photosynthetic reaction centers (RCs) in photovoltaic devices has been studied for some time. Solid state photosensitive devices have for example been described which employ isolated photosynthetic complexes (see U.S. Pat. No. 7,592,539). In some instances, RCs have been utilized in a manner analogous to dyes in a Dye-Sensitized Solar Cell (DSSC)-like cell. To facilitate efficient transfer of photogenerated charges in such devices, the RC layer must generally be well ordered, with the closest possible distance between the electrode surface and charge transfer sites in the RC. A potential drawback of this configuration, however, is inherently low device efficiency, for example due to relatively poor charge transfer or due to the fact that the layer of RC may not be thick enough to absorb a significant portion of the incident light. Any disorder in the RC layer may also reduce efficiency. In addition, DSSC-type devices may have a relatively short lifetime, due at least in part to the detachment of photoactive materials from the surface of the electrode.

### SUMMARY OF THE INVENTION

In one aspect, the invention relates to photovoltaic cells, and more particularly, to a photovoltaic charge storage device capable of photoelectric conversion and in-situ charge storage. In one aspect, the invention features a photovoltaic charge storage device, including at least the following: electrodes, a light absorbing species called the “photoelectric center” capable of transferring electrons to and from one or more charge transfer mediators, and a medium in which the photoelectric center and charge transfer mediator(s) are mobile, so that charge can be transferred from the photoelectric center to the electrodes. In the exemplified embodiments, there are two charge transfer mediators, exemplified by small molecule redox species, the first charge transfer mediator acting to transfer charge from the photoelectric center to the cathode, while the second charge transfer mediator acts to transfer charge from the photoelectric center to the anode.

In selected embodiments, the photoelectric center is immersed in the fluid medium and is capable of mobility therein, for example by diffusion. The photoelectric center is selected to receive electromagnetic radiation for photoelectric conversion. First and second redox species are also provided, capable of mobility in the medium. The photoelectric center, the first redox species, and the second redox species are selected such that, upon electromagnetic irradiation of the photoelectric center, the photoelectric center donates an electron (i.e., a photogenerated charge) to one redox species and receives an electron from the second redox species. As such, the photoelectric center provides charge generation, and redox species act to transfer charges between the photoelectric center and conductive contacts to be utilized in an external circuit. One redox species acts as a charge transporter for transferring the returning electrons, which flow through the external circuit back to the conductive contacts, to the photoelectric center to replenish the electron lost to a second redox species. The redox species can also store excess charge as chemical energy, for example when the required current for the load is less than the rate of charge generation, thereby providing a degree of in-situ charge storage.

The conductive contacts in the photovoltaic device may be a positive electrode and a negative electrode, at least partially immersed in the fluid medium, for conversion of the photogenerated charges from chemical energy into electrical energy. A container may be provided, for housing the medium, the first and second redox species, and the positive and negative electrodes, and adapted to allow electromagnetic radiation to reach the photoelectric center. In some embodiments, the positive electrode, the cathode, is selected so that the reduction of the first redox species at the surface thereof is faster than the oxidation of the second redox species at the surface thereof. Similarly, the negative electrode, the anode, may be selected so that the oxidation of the second redox species at the surface thereof is faster than the reduction of the first redox species at the surface thereof. In certain embodiments, the photovoltaic device is adapted to permit the photoelectric center in the medium to receive light energy, for example being configured to include a light-harvesting unit, through which the photoelectric center receives electromagnetic radiation.

### BRIEF DESCRIPTION OF THE DRAWINGS

FIG. 1 is a schematic of the structure and operation of a bio-photovoltaic device of the invention. The thick arrows represent reactions with high reaction rate constants, while the thin arrows represent reactions that may reduce cell efficiency.

FIG. 2a is a graph illustrating the open circuit potential of the cell described in Example 1 (light on, ↑; light off, ↓). FIG. 2b is a graph illustrating a photocurrent generated by the cell described in Example 1 (light on, ↑; light off, ↓).

FIG. 3a is a graph illustrating the open circuit potential of the cell described in Example 2 (Light on, ↑; light off, ↓). FIG. 3b is a graph illustrating a photocurrent generated by the cell described in Example 2 (light on, ↑; light off, ↓).

FIG. 4 is a graph illustrating the photocurrent response (light on, ↑; light off, ↓) for the cell described in Example 3, with an fluid electrolyte medium containing 15 μM RC, 0.75 mM ferrocene, and 0.75 mM methy viologen. The intensity of the incident light was 2.8 mW/cm2. The inset graph illustrates the transient response with larger magnification.

FIG. 5a is a graph illustrating the magnitude of the steady state photocurrent versus the light intensity for the cell of Example 3, with a fluid electrolyte medium containing 1.4 μM of RC. FIG. 5b is a graph illustrating the magnitude of the steady state photocurrent versus the concentration of RCs in the fluid medium of the same cell. The intensity of the incident light was 2.8 mW/cm².

FIG. 6a-d are a schematic illustrations of various configurations for a photovoltaic cell having components arranged to permit light energy to reach a photoelectric center housed in a medium in the cell.

FIG. 7 is a schematic illustration showing selected mediators and electrodes, with a selected relative spacing of energy levels that facilitates electron transfer and charge generation by the device of the invention.

### DETAILED DESCRIPTION OF THE INVENTION

In various aspects, the invention provides a device having both photoelectric conversion and storage functions integrated in a single cell structure. An illustrative embodiment of the device is provided, utilizing a selected photoelectric center, the RC from the bacterium Rhodobacter sphaeroides. This RC contains three subunits, L, M and H, and electron transfer cofactors. The cofactors include the primary electron donor (P) which is a bacteriochlorophyll dimer, two bacteriochlorophylls (B_{A} and B_{B}), two bacteriopheophytins (H_{A} and H_{B}), two ubiquinones (Q_{A} and Q_{B}), and one iron atom (Fe²⁺). The following processes are understood to occur in the photogeneration of charges in the RC. In a living cell, the absorption of a photon in a RC results in an electronically excited state at P. The excited electron is then thought to be transferred via B_{A}, H_{A} and Q_{A} cofactors to Q_{B} in 100 μs, developing a dipole across the RC. Working as a mobile protein hole carrier charge transfer mediator, a cytochrome donates an electron to the RC to neutralize the positive charge at P. After the absorption of two photons and neutralization of the two negative charges at Q_{B} by protonation, QH₂ (a ubiquinol) is formed. The QH₂ leaves the RC and a quinone (Q) fills the Q_{B} vacancy, with QH₂ acting as an electron carrier and charge transfer mediator. Put simply, an absorbed photon generates a pair of charges, positive and negative, inside the RC (acting as the photoelectric center). Due to the cofactor energy structure in the RC, the positive and negative charges are spatially separated in a very short time. In accordance with the invention, the separated charges in the RC may be transferred to two different mobile molecules, acting as charge transfer mediators. In alternative embodiments, for example, electrons may be removed at QA, or earlier in the charge separation sequence, for example by blocking transfer to Qb or elsewhere in the electron transport chain.

The separated charges can be removed from the RC by mediators, which in the exemplified embodiments, were ferrocene (Cp₂Fe) and methyl viologen (MV²⁺). In these reactions Cp₂Fe donates an electron to the P side of the RC and converts to Cp₂Fe⁺, whereas MV²⁺ is reduced to MV⁺ when an electron is removed from QB side of the RC. The reactions that occur at the RC are:

Cp₂Fe→e⁻+Cp₂Fe⁺ (1)

MV^{2++e}⁻→MV⁺ (2)

The mediators and RC are selected so that the redox reaction rates of the mediators with the RC are much faster than the rate of charge recombination within the RC, so that the equilibrium of the system is shifted towards charge transfer to the mediators rather than charge recombination within the RC. Charge recombination can also occur in a fluid electrolyte medium through interaction between the photoactivated mediators (Cp₂Fe⁺ and MV⁺), to convert them back to Cp₂Fe and MV²⁺:

Cp₂Fe⁺+MV⁺→Cp₂Fe+MV²⁺ (3)

In a medium containing the RC and the mediators, the concentrations of Cp₂Fe⁺ and MV⁺ increase with time upon illumination. The increase in the concentration results in a faster reaction rate for reaction (3) until the rate reaches a generation rate, G, resulting in a steady state.

The components of the system of the invention are selected so that the reduction rate of a first redox species, exemplified by Cp₂Fe⁺, at the surface of one of the electrodes, the cathode, is faster than both: the recombination rate in reaction (3); and, the oxidation rate of MV⁺ at the electrode. In this way, a photocathodic current is obtained from the electrode, the cathode, with the first redox species, eg. ferrocene, acting as the cathodes charge transfer mediator.

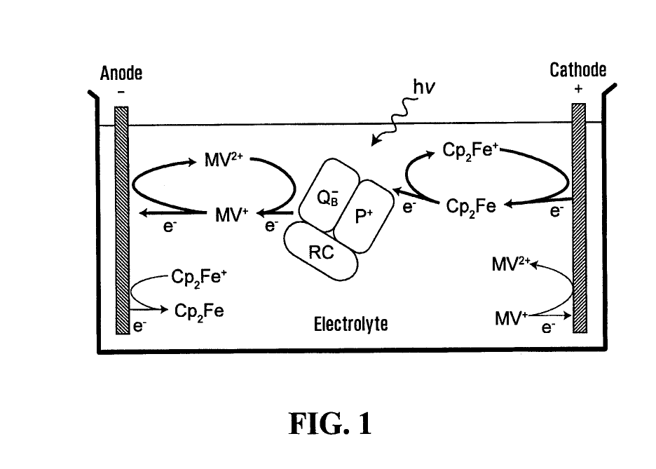

A second redox species is selected so that, at the anode, the oxidation rate of the second redox species, exemplified by methyl viologen MV⁺, is faster than both: the recombination rate in reaction (3); and, the reduction rate of the first redox species, exemplified by Cp₂Fe⁺, at the electrode. In effect, the second redox species, methyl viologen, acts as the anode charge transfer mediator to complete a steady state photocurrent in the device, as illustrated in FIG. 1.

In alternative embodiments, the charge transfer mediators may be selected from electrochemically active compounds capable of transferring electrons from the photoelectric center to the electrodes. Alternatives include, but are not limited to: thionines (e.g. acrylamidomethylthionine, Nfl-dimethyl-disulfonated thionine etc), viologens (e.g. benzylviologen, methyl viologen, polymeric viologens), quinones (e.g. 2-hydroxy-1,4-naphthoquinone, 2-methyl-1,4-naphthoquinone, 2-Methylnaphthoquinone), phenazines (e.g. phenazine ethosulfate, safranine), phenothiazines (e.g. alizarine brilliant blue, methylene blue, phenothiazine, toluidine blue), phenoxazines (e.g. brilliant cresyl blue, gallocyanine, resorufin), iron cyanide, ferric chelate complexes (e.g. Fe(III)EDTA), ferrocene derivates, iron cyanide, dichlorophenolindophenol, diaminodurene, quinol, or cytochrome C. For example, in selected embodiments, the first redox species, acting as a cathode charge transfer mediator, donating electrons to the photoelectric center, may be a cytochrome C, or ferrocene, and the second redox species, acting as an anode charge transfer mediator, accepting electrons from the photoelectric center, may be a methyl viologen, ubiquinone 10, or ubiquinone 50.

In some embodiments, the photoelectric centre may function as one of the charge transfer mediators, so that only a single redox species is required. In embodiments of this kind, the photoelectric centre itself interacts with one of the electrodes to mediate electron transfer.

In alternative embodiments, the electrodes may be selected from a variety of materials, having electronic band structures that selectively facilitate electron transfer with the relevant charge transfer mediator (favoring the appropriate reaction, as illustrated in FIG. 1). Potential electrode materials include, for example platinum, platinum-black, gold, silver, indium tin-oxide, tungsten oxide, tin oxide, germanium, carbon, reticulated vitreous carbon, carbon felt, glassy carbon, graphite, graphite felt, noble metals, solid or porous conductive plastics, or mixtures thereof. In alternative embodiments, the selectivity of the electrode for the relevant charge transfer mediator may be orchestrated by physical or chemical exclusion of the other charge transfer mediator, for example by coating an electrode with a membrane or lipid layer. Accordingly, in some embodiments, at least one electrode may be chosen such that it is selective for one mediator by using steric hindrance, or size exclusion, for example based on a size selective means such as a coating or, membrane having selected pore sizes, or by hydrophobicity, for example using a lipid layer at the electrode surface to exclude a cytochrome. In alternative embodiments, the spacing between the electrodes and the mediator concentrations may be selected to facilitate a desired mass transport rate.

In some embodiments, the anode may for example be comprised of a wide band gap, transparent semiconductor (such as tungsten oxide and tin oxide), or a transparent organic semiconductor. Table 1 shows a list of candidate semiconductors that may be used as electrodes in alternative embodiments, with conduction and valence band energies versus vacuum level. In alternative embodiments, the cathode electrode may for example be made from a hole transporting organic material with Highest Occupied Molecular Orbital (HOMO) around 5.0 eV. Examples are copper phthalocyanine (CuPC) and bis(carbazolyl)benzene (BCB). Similarly the cathode may be a conducting polymer or other low bandgap semiconductor (such as germanium). Also, a thin film of organic materials may be applied on the surface of each electrode as the electron blocking or hole blocking layer. Examples of electron blocking materials are tris(8-hydroxyquinoline) aluminum (Alq3) and 2,9-dimethyl-4,7-diphenyl-1,10-phenanthroline (BCP). An example of a hole blocking material is poly(3,4-ethylenedioxythiophene):poly(styrene sulfonate) (PEDOT:PSS).

TABLE 1
Candidate semiconductors for electrodes

| Materials | Ec (eV) | Ev (eV) | Suitable for |
|---|---|---|---|
| SnO₂ | 5.0 | 8.8 | Anode |
| WO₃ | 4.8 | 8.0 | Anode |
| Fe₂O₃ | 5.0 | 7.1 | Anode |
| Ge | 4.0 | 4.66 | Cathode |

| | | |
|---|---|---|
| CuPC | HOMO = 5.6 eV | Cathode |
| BCB | HOMO = 5.1 eV | Cathode |

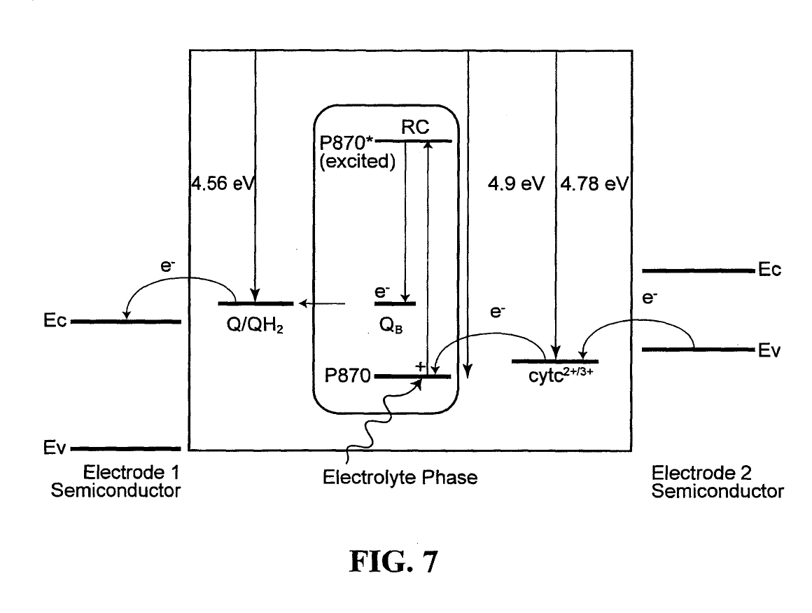

FIG. 7 illustrates the relative spacing of energy levels in selected embodiments, with mediators selected to have a redox potential that is similar to or lower than the energy of the electron donor site on the RC or other photoelectric center (illustrated at QB, with alternatives higher up the electron transport chain). The mediator donating electrons to the photoelectric center (RC) may be chosen to have a redox potential that is similar to or higher than the potential of the electron acceptor site on the photoelectric center (RC). For semiconducting electrodes to be selective, the conduction band edge of one electrode is similar to or lower in energy than the redox potential of the electron transporting mediator. The conduction band of the other electrode should be significantly higher so that electron transfer is negligible. The valence band edge of the other electrode may be similar to or higher than the redox potential of the mediator that donates electrons to the photoelectric center (RC). In selected embodiments, the valence band of the first electrode is lower, so that electron transfer to this mediator is small.

The medium in which the photoelectric centre and the redox species are mobile may be a fluid medium, such as an aqueous solution. The solution may for example be a buffered solution, selected to provide a particular pH that facilitates the generation of current, and/or a pH that limits the charge transfer reaction between mediators in the medium, i.e. between the reduced anode charge transfer mediator and the oxidized cathode charge transfer mediator. For example, cytrochrome c in the 3⁺ oxidation state and quinol react more slowly at low pH levels. The fluid medium may have a wide range of viscosities, and may for example be a gel.

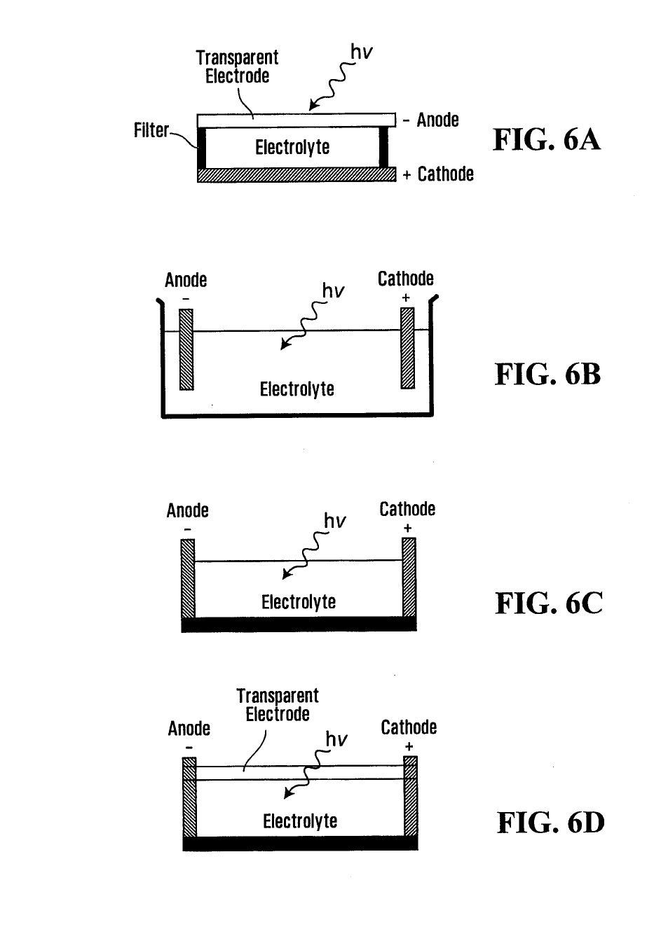

As illustrated in FIG. 6, the device of the invention is adapted to permit electromagnetic radiation of an appropriate wavelength reach the photoelectric center. For example, one or more of the electrodes may be permissive to passage of light, for example being transparent, as shown in FIG. 6a. Similarly, the medium, identified as the electrolyte in the Figures, may be permissive or transparent to light of the appropriate wavelength. As shown in FIG. 6d, parts of the housing that enclose the medium may provide a window that permits passage of light through to the medium.

In selected embodiments, the device of the invention accordingly includes a fluid medium, a photoelectric center, first and second redox species (acting as a cathode charge transfer mediator and an anode charge transfer mediator respectively). The photoelectric center may be immersed in the fluid medium, and may be capable of mobility in the medium. The photoelectric center, redox species and electrolyte are selected so that, under illumination:
the redox reaction rates of the mediators with the RC are faster than both:
   the rate of charge recombination within the RC; and,
   the rate of recombination between the activated mediators in the electrolyte.

Similarly, the redox species, electrolyte and the electrode materials are selected so that:
the reduction of the first redox species at the cathode is faster than the oxidation of the second redox species at the cathode, so that the first redox species functions as a cathode charge transfer mediator; and,
the oxidation of the second redox species at the anode is faster than the reduction of the first redox species at the anode, so that the second redox species functions as an anode charge transfer mediator.

The photoelectric centre may for example be a biological RC or photosystem, such as a photosystem II from a plant or a naturally occurring RC from bacteria, plants, algae or cyanobacteria, such as RCs from themophillic organisms such as Chloroflexus aurantiacus or Chromatium tepidum, or from acidotolerant organisms such as Rhodoblastus sphagnicola or Acidiphilium rubrum. In alternative embodiments, a modified biological RC may be used (modified for example to receive a broader bandwidth of electromagnetic radiation for photoelectric conversion). The photoelectric center may alternatively be produced synthetically, for example as described in “Artificial Photosynthesis, From Basic Biology to Industrial Applications” Ed. by Anthony F. Collings and Christa Critchley, Wiley-VCH, 2005, including embodiments illustrated therein in Chapter 10 (incorporated herein by reference). In alternative embodiments, the RC complexes of plants and algae may be used, in addition to bacterial RCs such as the exemplified RC of the bacterium R. sphaeroides. In selected embodiments, the light absorption efficiency of the cell may be enhanced by incorporating light-harvesting complexes, and/or by the simultaneous use of two or more photoelectric centers to improve spectral coverage. For example bacterial and plant RCs may be selected that absorb in complementary spectral regions. Alternatively, RCs may be used with biological or non-biological light harvesting complexes, comprising molecular species that function to absorb light across a broader range of wavelengths than an RC alone, transferring the electrochemical energy to the RC where the electrical dipole is created and maintained.

In selected embodiments, the first redox species (m₁) and second redox species (m₂) are capable of mobility in the fluid medium. The photoelectric center, the first redox species, and the second redox species may advantageously be selected so that irradiation of the photoelectric center causes the photoelectric center to donate an electron to the second redox species and to receive an electron from the first redox species. In some embodiments, the mediators may accordingly be selected to function more efficiently with a particular combination of photoelectric center, anode, and cathode. For example, the RC of R. sphaeroides is capable of accepting electrons from several types of cytochrome, ferrocene, diaminodurene (DAD; 2,3,5,6-tetramethyl-p-phenylenediamine), PMS (N-methylphenazonium methosulfate), DCPIP (dichlorophenolindophenol), or ferrocyanide. Examples of substances that are capable of accepting electrons from the R. sphaeroides RC are a variety of quinones, notably ubiquinones (1,4-benzoquinone with isoprenyl sidechain numbers ranging from 0-10), methyl viologen, and benzyl viologen.

Referring to the embodiment schematically illustrated in FIG. 1, a photovoltaic device is provided in the form of an electrochemical cell. The cell has two electrodes immersed in the fluid medium containing: a photoelectric center, a first redox species (m₁), and a second redox species (m₂). In the illustrated embodiment, the photoelectric center is a biological reaction center (RC). The redox species act as charge transfer mediators. When a photon (hv) is absorbed, a dipole is developed across the RC. Two mediators (m₁ and m₂) transfer charges to the electrodes. The first mediator (m₁) is selected so that it will be readily oxidized by donating an electron to the P in the RC. The second mediator (m₂) is selected so that it will be reduced by receiving an electron from Q_{B}. The anode is formed from a material that can oxidize m₂. The cathode is selected from a material suitable for reduction of m₁₊. Since the photo-generated charges are first transferred to the mediators m₁ and m₂, the photovoltaic charge storage device can store electrochemical charge when the required current for the load is less than the rate of charge generation. In this circumstance, the voltage generated by the device can increase with time when it is illuminated.

Electrodes can be made selective, for example, by using semiconductors that primarily accept or donate charge from only one mediator. For example, tungsten oxide and germanium may be used in combination as selective electrodes, with the tungsten oxide receiving electrons at one side of the cell, and germanium donating electrons at the other. Alternative electrodes include other traditional semiconductors, as well as organic semiconductors that are tailored to accept electrons or to donate electrons. Electrodes can also be made selective by using a means of preventing one mediator from accessing the surface while allowing the other to reach it, for example by using a size exclusion coating or membrane or by changing the chemical affinity. A difference in reaction rate kinetics at the electrodes can also be used to maximize current.

In selected embodiments, a relatively high concentration of photoelectric centers, such as RCs, may be provided in the fluid medium to enhance light absorption and current generation. The depth and configuration of the cell can similarly be designed to accommodate the light penetration depth for a chosen concentration of RCs.

To obtain higher current and longer charge stability, the material of the cathode may be chosen to provide relatively fast reduction of m₁₊ and a relatively slow oxidation of m₂. Similarly, a relatively fast oxidation of m₂₋ and slow reduction of m₁₊ at the anode are also desirable to maximize the conversion of the photogenerated charges into electrical energy. In addition, charge transfer mediators may be selected so that the rate of m₁₊+m₂₋→m₁+m₂ is relatively slow, to minimize dissipation of energy stored in the fluid medium.

Although various embodiments of the invention are disclosed herein, many adaptations and modifications may be made within the scope of the invention in accordance with the common general knowledge of those skilled in this art. Such modifications include the substitution of known equivalents for any aspect of the invention in order to achieve the same result in substantially the same way. Numeric ranges are inclusive of the numbers defining the range. The word “comprising” is used herein as an open-ended term, substantially equivalent to the phrase “including, but not limited to”, and the word “comprises” has a corresponding meaning. As used herein, the singular forms “a”, “an” and “the” include plural referents unless the context clearly dictates otherwise. Thus, for example, reference to “a thing” includes more than one such thing. Citation of references herein is not an admission that such references are prior art to the present invention. Any priority document(s) and all publications, including but not limited to patents and applications, cited in this specification are incorporated herein by reference as if each individual publication were specifically and individually indicated to be incorporated by reference herein and as though fully set forth herein. The invention includes all embodiments and variations substantially as hereinbefore described and with reference to the examples and drawings.

### EXAMPLES

### Example 1

### Metallic Electrodes with Non-Biological Mediators

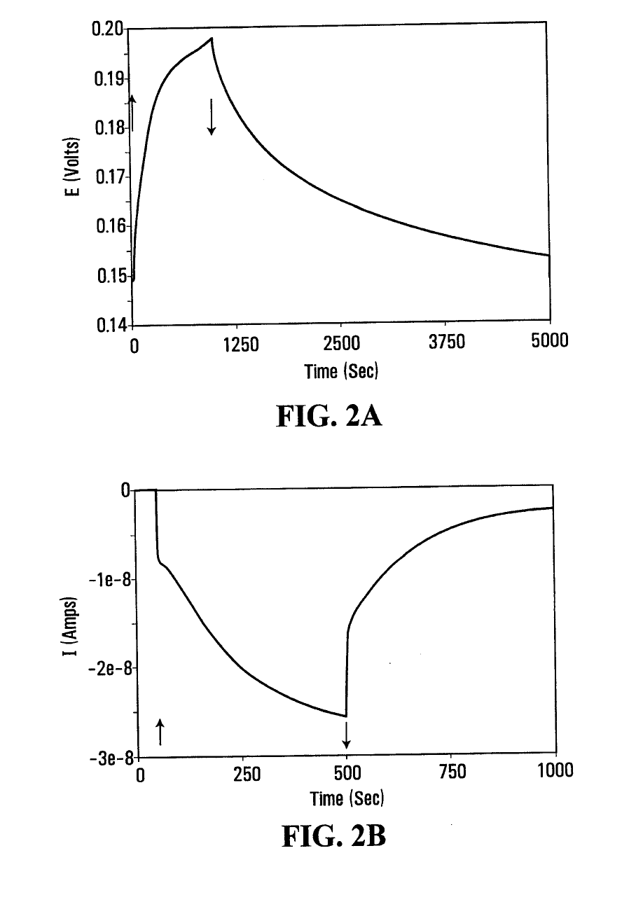

A photovoltaic device was prepared using a 4 mL transparent cuvette as a container with a piece of highly ordered pyrolytic graphite (HOPG) and a piece of Pt wire as the anode and cathode electrodes, respectively. The electrolyte was a 100 mM Tris-HCl buffer (pH 8.0) containing 0.2 μM RC (from R. sphaeroides), 7.8 mM methyl viologen as m₂ mediator, and 0.2 mM of ferrocene as m₁ mediator. The RC of R. sphaeroides oxidizes ferrocene and reduces methyl viologen upon illumination. The open circuit potential of the cell shows that the cell is charged upon illumination (FIG. 2a). When the light was turned off, the voltage dropped gradually, taking more than one hour to discharge. The cell was also delivering current during and after illumination (FIG. 2b). The persistence of a current after cessation of illumination illustrates the charge storage capacity of the photovoltaic device.

### Example 2

### Semiconducting/Metallic Electrodes with Biological Mediators

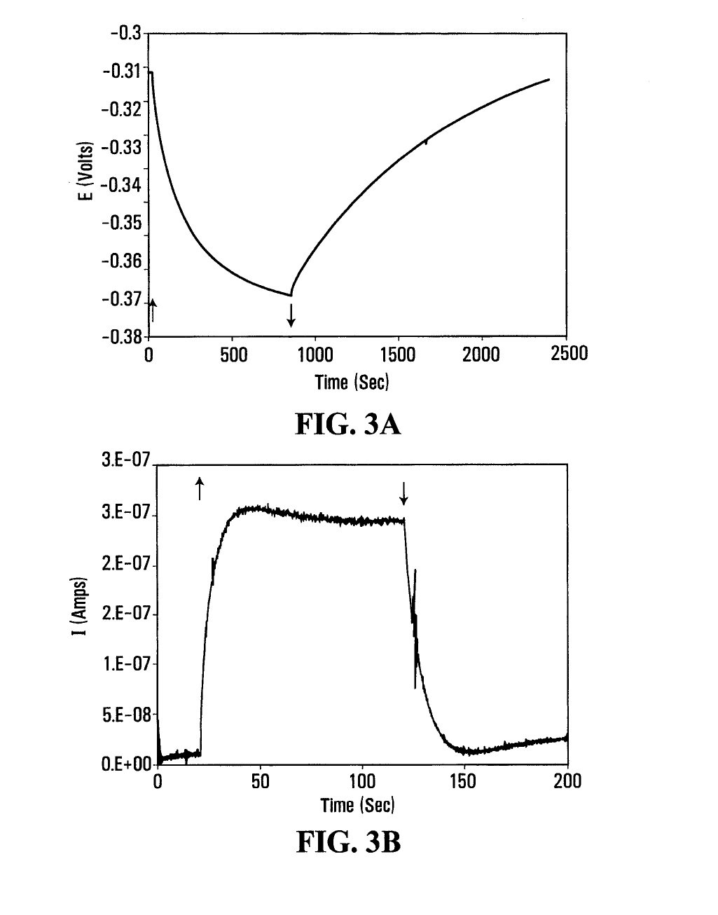

A photovoltaic device was prepared using a 4 mL transparent cuvette as a container with a piece of Tungsten Oxide (WO₃) and a piece of Carbon paper as the anode and cathode electrodes, respectively. WO₃ is a semiconducting material and carbon paper has metallic properties. The electrolyte was a 100 mM Tris-HCl buffer (pH 8.0) containing 5 μM RC and 80 μM quinone as m₂ mediator and 80 μM of cytochrome as m₁ mediator. The RC of R. sphaeroides oxidizes cytochrome and reduces quinone upon illumination. The open circuit potential of the cell shows that the cell is charged upon illumination (FIG. 3a). When the light was turned off, the voltage dropped. The cell was also delivering current during and after illumination (FIG. 3b). Again, the persistence of a current after cessation of illumination illustrates the charge storage capacity of the photovoltaic device.

### Example 3

### Enhanced Light Absorption

A photovoltaic device was fabricated in a 4 mL glass fluorometer cuvette (1 cm×1 cm path length). Cultures of R. sphaeroides strain ΔPUHAΔPUC containing a plasmid expressing a His-tagged RC H protein were grown as previously described [Abresch et al., 2005], and the RC purified as described [Goldsmith and Boxer, 1996]. The concentration of RC after purification was 18 μM, based on the absorption peak at 804 nm. An aqueous solution of 0.75 mM Cp₂Fe and 0.75 mM MV²⁺ (both from Sigma) in Tris-HCl buffer (pH 8), 0.1% N,N-dimethyl-dodecylamine N-oxide (LDAO), and various concentrations of the RC were used as the electrolyte. The concentration of mediators is chosen to be much higher than the RC concentration so as not to limit the photocurrent with a shortage of mediators. The solubility of ferrocene is limited to 0.8 mM. Highly ordered pyrolytic graphite (HOPG) was used for the cathode and a platinum wire for the anode [Takshi et al., 2009]. The HOPG, purchased from SPI, was a freshly cleaved layer with an area of 1 cm². The area of the platinum wire was 0.5 cm². The photocurrent in the electrochemical cell was measured with a Solartron SI 1287 electrochemical interface. To eliminate the effect of ambient light the electrochemical cell was placed in a black box equipped with an electrical shutter. Using an Oriel solar simulator (AM 1.0) a beam of white light with an incident intensity of 2.8 mW/cm² illuminated a side of the cell through an optical fiber. During measurement, a voltage equal to the open circuit potential in the dark was applied across the cell and the current recorded upon illumination [Trammell et al., 2004].

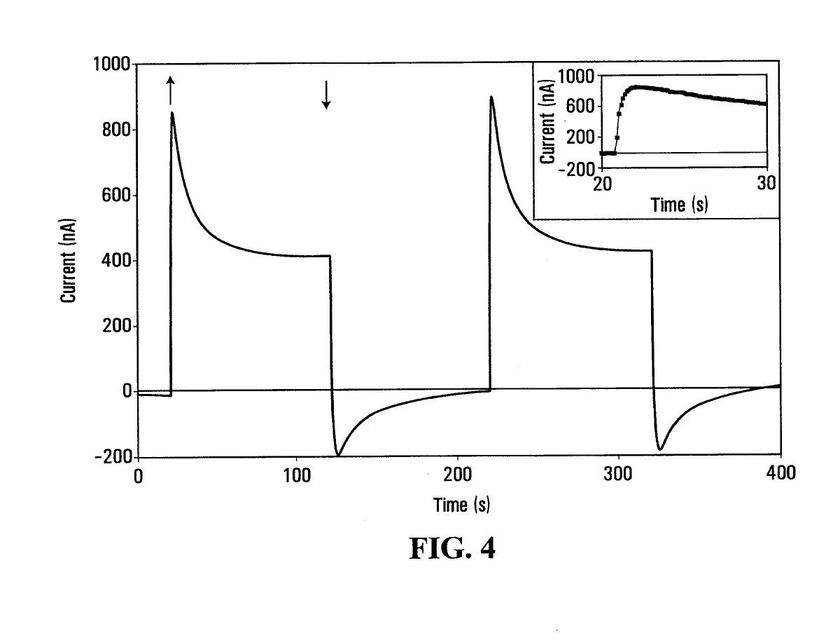

In the absence of the RC in the electrolyte, no photocurrent was detected when the cell was illuminated. A very small photocurrent (˜2 nA) was measured in a cell with an electrolyte containing the RC but no mediators. Using an electrolyte with 15 μM of RC, 0.75 mM of Cp₂Fe and 0.75 mM of MV²⁺, the current responded to the light (FIG. 4). The rapid increase in the current and the gradual drop in the transient response are likely due to different reaction rates of competing mediators at the surface of the electrodes. Assuming that reduction of Cp₂Fe⁺ and oxidation of MV⁺ take place with different rates at the electrode surfaces, the total current is expected to be a superposition of a cathodic and an anodic current, each having different time constants. The difference between rates also determines the steady state photocurrent. The measured current did not change when the electrode surface area was reduced by a factor of two, indicating that the surface area of the electrodes and kinetics of electron transfer at the electrode surfaces are not limiting the current. Also, no change in the performance was observed when the device was illuminated for a few hours. However, the performance was degraded in a few days even when the cell was not illuminated, which may be due to the denaturalization of the proteins at room temperature.

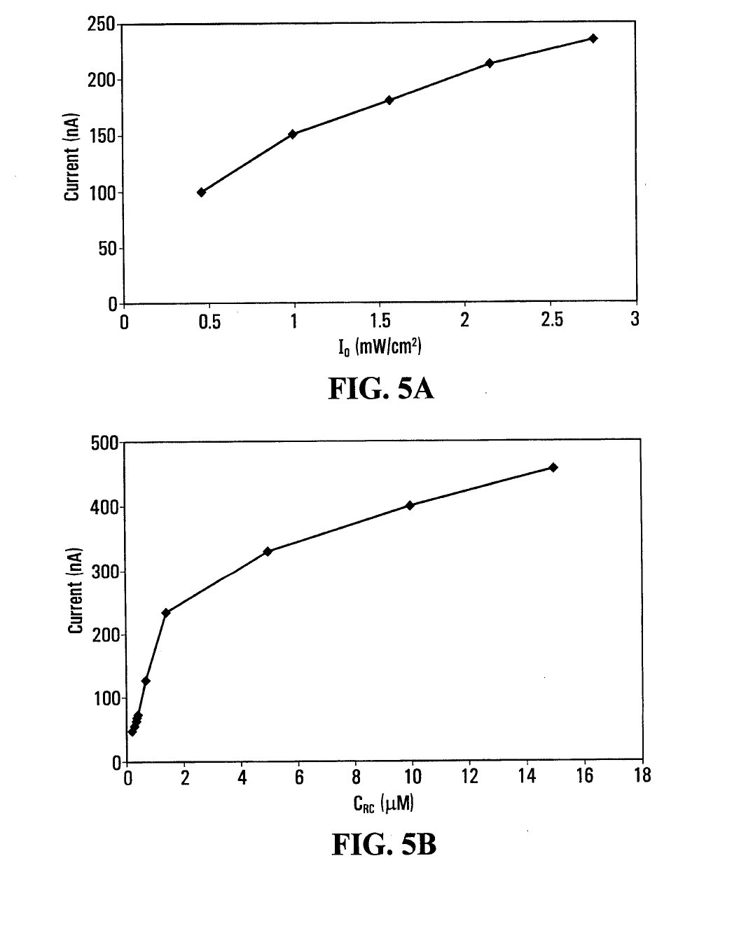

In order to study the effect of light intensity, the photocurrent was measured using several intensities. As shown in FIG. 5a, the value of the steady state current changes almost linearly with the variations in the light intensity. The current was also recorded for different concentrations of RC ranging between 0.2 and 15 μM. As shown in FIG. 5b, the photocurrent increased with the increase in the concentration of the RC with a trend predicted by equation (4).

In alternative embodiments, in order to facilitate more selective reactions at each electrode, semiconducting electrodes with energy levels that match with the reaction potentials may be used. Similarly, alternative mediators may function more efficiently.

### REFERENCES

Blankenship, R. E. Natural Organic Photosynthetic Solar Energy Transduction. In Organic Photovoltaics; Sun, S. S., Sariciftci, N. S., Eds.; CRC Press: Boca Raton, Fla., USA, 2005; Chapter 3; pp. 1-12.

Sundström, V. Light in elementary biological reactions. Prog. Quantum Electron. 2000, 24, 187-238.

Seibert, M.; Janzen, A. F.; Kendall-Tobias, M. Light-induced electron transport across semiconductor electrode/reaction-center film/electrolyte interfaces. Photochem. Photobiol. 1981, 35, 193-200.

Zhao, J.; Liu, B.; Zou, Y.; Xu, C.; Kong, J. Photoelectric conversion of photosynthetic reaction center in multilayered films fabricated by layer-by-layer assembly. Electrochim. Acta 2002, 47, 2013-2017.

Lebedev, N.; Trammell, S. A.; Tsoi, S.; Spano, A.; Kim, J. H.; Xu, J.; Twigg, M. E., Schnur, J. M. Increasing Efficiency of Photoelectronic Conversion by Encapsulation of Photosynthetic Reaction Center Proteins in Arrayed Carbon Nanotube Electrode. Langmuir 2008, 24, 8871-8876.

Lu, Y.; Yuan, M.; Liu, Y.; Tu, B.; Xu, C.; Liu, B.; Zhao, D.; Kong, J. Photoelectric Performance of Bacteria Photosynthetic Proteins Entrapped on Tailored Mesoporous WO3-TiO2 Films. Langmuir2005, 21, 4071-4076.

Trammell, S. A.; Wang, L.; Zullo, J. M.; Shashidhar, R.; Lebedev, N. Orientated binding of photosynthetic reaction centers on gold using Ni-NTA self-assembled monolayers. Biosens. Bioelectron. 2004, 19, 1649-1655.

Trammell, S. A.; Spano, A.; Price, R.; Lebedev, N. Effect of protein orientation on electron transfer between photosynthetic reaction centers and cargon electrodes. Biosens. Bioelectron. 2006, 21, 1023-1028.

Takshi, A.; Madden, J. D.; Beatty, J. T. Diffusion model for charge transfer from a photosynthetic reaction center to an electrode in a photovoltaic device. Electrochim. Acta 2009, 54, 3806-3811.

Katz, E. Application of bifunctional reagents for immobilization of proteins on a carbon electrode surface: Oriented immobilization of photosynthetic reaction centers. J. Electroanal. Chem. 1994, 365,157-164.

Feher, G.; Allen, J. P.; Okamura, M. Y.; Rees, D. C. Structure and function of bacterial photosynthetic reaction centres. Nature 1989, 339, 111-116.

Turzo, K.; Laczko, G.; Filus, Z.; Maroti, P. Quinone-Dependent Delayed Fluorescence from the Reaction Center of Photosynthetic Bacteria. Biophys. J. 2000, 79,14-25.

Takahashi, E.; Wraight, C. A. Small Weak Acids Reactivate Proton Transfer in Reaction Centers from Rhodobacter sphaeroides Mutated at AspL210 and AspM17. J. Biol. Chem. 2006, 281, 4413-4422.

Suemori, Y.; Nagata, M.; Nakamura, Y.; Nakagawa, K.; Okuda, A.; Inagaki, J. I.; Shinohara, K.; Ogawa, M.; Iida, K; Dewa, T.; Yamashita, K.; Gardiner, A.; Cogdell, R. J.; Nango, M. Self-assembled monolayer of light-harvesting core complexes of photosynthetic bacteria on an amino-terminated ITO electrode. Photosynth. Res. 2006, 90, 17-21.

Gregg, B. A.; Hanna, M. C. Comparing organic to inorganic photovoltaic cells: Theory, experiment, and simulation. J. Appl. Phys. 2003, 93, 3605-3614.

Abresch, E. C.; Axelrod, H. L. A.; Beatty, J. T.; Johnson, J. A.; Nechushtai, R.; Paddok, M. L. Characterization of a Highly Purified, Fully Active, Crystallizable RC-LH1-PufX Core Complex from Rhodobacter sphaeroides. Photosynth. Res. 2005, 86, 61-70.

Goldsmith, J. O.; Boxer, S. G. Rapid isolation of bacterial photosynthetic reaction centers with an engineered poly-histidine tag. Biochim. Biophys. Acta, Biophys. 1996, 1276, 171-175.

Schonfeld, M.; Montal, M; Feher, G. Functional reconstitution of photosynthetic reaction centers in planar lipid bilayers. P.N.A.S. 1979, 76,6351-6355.

1. A photovoltaic device having a cell comprising:
a cathode and an anode electrically coupled to an electrical circuit;
a medium in contact with the cathode and the anode;
a molecular photoelectric center dispersed and mobile in the medium; and, one or both of:
a first redox species dispersed and mobile in the medium, wherein the first redox species accepts electrons from the cathode, to form a reduced cathode charge transfer mediator, and donates electrons to the photoelectric center, to form an oxidized cathode charge transfer mediator; and,
a second redox species dispersed and mobile in the medium, wherein the second redox species accepts electrons from the photoelectric center, to form a reduced anode charge transfer mediator, and donates electrons to the anode, to form an oxidized anode charge transfer mediator;
wherein, the photoelectric centre absorbs electromagnetic irradiation to form an activated photoelectric centre having an electric dipole, the dipole having a rate of decay by charge recombination within the photoelectric centre.

2. The device of claim 1, wherein:
a) the redox reaction rates of the reduced cathode charge transfer mediator and the oxidized anode charge transfer mediator with the activated photoelectric center are each greater than both:
i) the rate of decay of the dipole in the photoelectric centre; and,
ii) a rate at which the reduced anode charge transfer mediator reduces the oxidized cathode charge transfer mediator in the medium;
b) the rate of reduction of the first redox species at the cathode is greater than the rate of oxidation of the second redox species at the cathode; and,
c) the rate of oxidation of the second redox species at the anode is greater than the rate of reduction of the first redox species at the anode;
and the cell thereby mediates a potential difference in the circuit.

3. The device of claim 1, wherein the medium is a fluid medium.

4. The device of claim 3 wherein the fluid medium is a gel or an aquous solution.

5. The device of claim 3, wherein the fluid medium is a pH buffered fluid medium.

6. The device of claim 1, wherein the photoelectric center comprises a reaction centre of R. sphaeroides and the first redox species is a cytochrome, ferrocene, diaminodurene (DAD; 2,3,5,6-tetramethyl-p-phenylenediamine), PMS (N-methylphenazonium methosulfate), DCPIP (dichlorophenolindophenol), or ferrocyanide.

7. The device of claim 1, wherein the photoelectric center comprises a reaction centre of R. sphaeroides and the second redox species is a quinone, ubiquinone, 1,4-benzoquinone with isoprenyl sidechain numbers ranging from 0-10, methyl viologen, or benzyl viologen.

8. The device of claim 1, wherein the photoelectric center comprises or consists of a synthetic photoelectric center, a biological photosynthetic reaction center, a biological photosystem, a photosystem I, a photosystem II from a plant or a photosynthetic reaction center from a bacteria, plant, algae or cyanobacteria.

9. The device of claim 1, wherein the cathode or the anode comprise one or more of platinum, platinum-black, gold, silver, indium tin-oxide, tungsten oxide, tin oxide, germanium, carbon, reticulated vitreous carbon, carbon felt, glassy carbon, graphite, graphite felt, a noble metal, a solid conductive plastic, a porous conductive plastic, a wide band gap transparent semiconductor, a transparent organic semiconductor, a conducting polymer, or a low bandgap semiconductor.

10. The device of claim 1, wherein only one of the first and second redox species is present, and the photoelectric center functions as the other redox species.

11. The device of claim 1, wherein the cell comprises a component that is transparent to the electromagnetic radiation.

12. The device of claim 11, wherein the anode or the cathode is the component.

13. The device of claim 2, wherein the medium is a fluid medium.

14. The device of claim 13 wherein the fluid medium is a gel or an aquous solution.

15. The device of claim 13, wherein the fluid medium is a pH buffered fluid medium.

16. The device of claims 2, wherein the photoelectric center comprises a reaction centre of R. sphaeroides and the first redox species is a cytochrome, ferrocene, diaminodurene (DAD; 2,3,5,6-tetramethyl-p-phenylenediamine), PMS (N-methylphenazonium methosulfate), DCPIP (dichlorophenolindophenol), or ferrocyanide.

17. The device of claim 2, wherein the photoelectric center comprises a reaction centre of R. sphaeroides and the second redox species is a quinone, ubiquinone, 1,4-benzoquinone with isoprenyl sidechain numbers ranging from 0-10, methyl viologen, or benzyl viologen.

18. The device of claim 2, wherein the photoelectric center comprises or consists of a synthetic photoelectric center, a biological photosynthetic reaction center, a biological photosystem, a photosystem I, a photosystem II from a plant or a photosynthetic reaction center from a bacteria, plant, algae or cyanobacteria.

19. The device of claim 2, wherein the cathode or the anode comprise one or more of platinum, platinum-black, gold, silver, indium tin-oxide, tungsten oxide, tin oxide, germanium, carbon, reticulated vitreous carbon, carbon felt, glassy carbon, graphite, graphite felt, a noble metal, a solid conductive plastic, a porous conductive plastic, a wide band gap transparent semiconductor, a transparent organic semiconductor, a conducting polymer, or a low bandgap semiconductor.

20. The device of claim 2, wherein only one of the first and second redox species is present, and the photoelectric center functions as the other redox species.

21. The device of claim 2, wherein the cell comprises a component that is transparent to the electromagnetic radiation.

22. The device of claim 21, wherein the anode or the cathode is the component.
